(19) United States
(12) Patent Application Publication
(10) Pub. No.: US 2005/0128726 A1
(43) Pub. Date: Jun. 16, 2005

(54) System and method for protecting pins of an integrated circuit

(76) Inventors: Jill H. Thompson, Watertown, MA (US); Richard E. Olson, Rindge, NH (US); David W. Mayer, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/732,396

(22) Filed: Dec. 10, 2003

(51) Int. Cl. H05K 7/00

(52) U.S. Cl. 361/820

(57) ABSTRACT

An apparatus for protecting pins of an integrated circuit comprises a cover member; and at least one securing mechanism for securing the cover member to an assembly that includes at least one integrated circuit having pins, wherein the cover member covers at least the pins.

### BACKGROUND

Integrated circuits are semiconductor wafers on which thousands or millions of tiny resistors, capacitors, and transistors may be fabricated. An integrated circuit may function as an amplifier, oscillator, timer, counter, computer memory, or a microprocessor, as examples.

Integrated circuits are advantageous for many reasons, including their small size. However, the small size may cause integrated circuits to be fragile. Most integrated circuits, such as microprocessors, contain pins. A pin is a pronged contact attached to, for example, the microprocessor that operates to provide a signal interface for the microprocessor to other devices. The pronged contacts are part of a male connector that plugs into various female connectors. For instance, these pins allow microprocessors to connect to sockets of a circuit board, such as a mother board in a computer, in order for the microprocessor to receive signals from the mother board and interact with other components.

The pins of integrated circuits are typically small and fragile and, therefore, are easily and frequently damaged. Damage to the pins often occurs during packaging, shipment or general handling of the integrated circuits. Unfortunately, damage to the pins often leads to permanent damage of the integrated circuit.

### BRIEF SUMMARY

In one embodiment of the invention, an apparatus for protecting pins of an integrated circuit comprises a cover member; and at least one securing mechanism for securing the cover member to an assembly that includes at least one integrated circuit having pins, wherein the cover member covers at least the pins.

In another embodiment, a protector for protecting pins of a microprocessor comprises a rectangular shaped top face; a rectangular shaped bottom face; a plurality of sides; a plurality corners; a plurality of securing mechanisms attached to the corners projecting downward from the corner away from the top face; two label viewing sections formed in two opposing sides of the plurality of sides wherein the label viewing sections provide visibility for at least one label on the microprocessor; two installation cutout sections taken from two opposing sides of the plurality of sides not containing the label viewing sections wherein the installation cutout sections provide ease of installation and removal of the protector; at least two alignment sections; and at least two ribs operating to strengthen the protector.

In another embodiment, a shipping assembly for shipping an integrated circuit having pins comprises a base mechanism; a connection device for securing the integrated circuit to the base mechanism; and a pin protector installed over the pins of the integrated circuit, wherein the pin protector comprises a cover member; and at least one securing mechanism for securing the pin protector to the base mechanism wherein the pin protector covers the pins.

In another embodiment, a method of protecting the pins of an integrated circuit comprises providing a protector mechanism having a top face, a bottom face, a plurality of sides, a plurality of corners, at least one alignment section, at least one rib, and at least one securing mechanism; positioning the protector over the integrated circuit such that the protector extends over the pins; and attaching the protector to the integrated circuit.

In another embodiment, a mechanism for protecting the pins of an integrated circuit comprises a means for covering pins of an integrated circuit; a means for aligning the covering means to an assembly including an integrated circuit; and a means for securing the covering means to the assembly.

In another embodiment, a method for protecting the pins of an integrated circuit comprises positioning a cover member over the portion of the integrated circuit containing the pins; and urging the cover member into a snap fit attachment with the integrated circuit.

### BRIEF DESCRIPTION OF THE DRAWINGS

FIGS. 1A-1C show a top, bottom, and cross sectional view, respectively, of one embodiment of a pin protector;

FIG. 2 illustrates a processor shipping configuration;

FIG. 3 is an exploded view of FIG. 2 including one embodiment of a pin protector;

FIG. 4 is a non-exploded view of FIG. 3;

FIG. 5 is an upside down view of the exemplary arrangement of FIGS. 3 and 4;

FIG. 6 is a cross sectional view of FIG. 5;

FIG. 7 is a flowchart illustrating an application of an embodiment for protecting pins of an integrated circuit; and

FIG. 8 is a flowchart illustrating a method of protecting pins of an integrated circuit.

### DETAILED DESCRIPTION

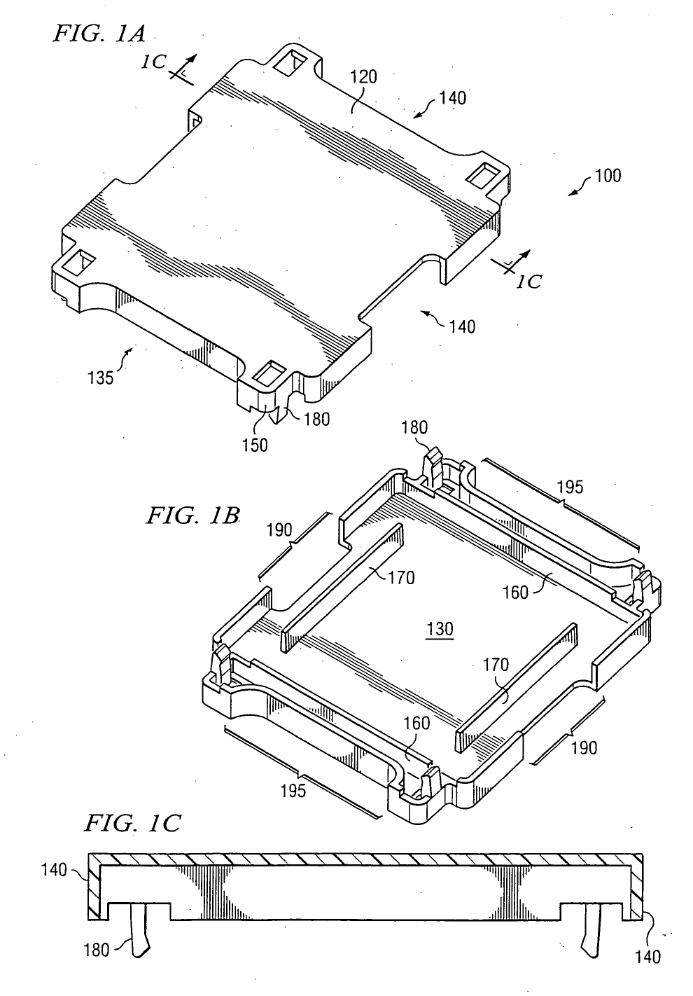

FIGS. 1A-1C illustrate a top, bottom, and side view, respectively, of one embodiment of a pin protector. A typical installation of pin protector 100 entails pin protector 100 being placed over an integrated circuit, such as computer memory or a microprocessor, and secured to the integrated circuit or accompanying hardware to cover and protect the integrated circuit's pins.

As illustrated in FIG. 1A, pin protector 100 includes a top face 120, a peripheral skirt 135 which in this embodiment comprises sides 140 and corners 150, and at least one securing mechanism 180. Top face 120 is a flat planar section that makes up the top of pin protector 100. Sides 140 are located around the perimeter of top face 120 and extend downward from top face 120. Comers 150 are located at the four corners of top face 120. Comers 150 are illustrated in FIG. 1A as rounded, however pin protector 100 may be arranged so that the corners are not rounded. In a circular shaped embodiment (not shown), the corners 150 may be entirely eliminated. Securing mechanism 180 may be positioned at corner 150 as illustrated in FIG. 1A.

Securing mechanism 180 may be used to secure pin protector 100 to the integrated circuit that is being protected or it may be used to secure pin protector 100 to any other accompanying hardware. For example, securing mechanism 180 may be used to secure pin protector 100 to a heat sink that accompanies a microprocessor whose pins are being protected. Securing mechanism 180 may be a snap, clip, latch or any mechanism suitable for securing pin protector 100 to an integrated circuit or its accompanying hardware.

FIG. 1B illustrates a bottom view of pin protector 100. The bottom view illustrates bottom face 130, alignment sections 160, ribs 170, installation cutout sections 190, label recessed sections 195, and securing mechanisms 180. Bottom face 130 is a flat planar section that is the underside of top face 120.

When “attached” is used in conjunction with describing the location of the various components of pin protector 100, it is used to imply that the various components are located as described as a result of a molding or other forming process. “Attached” does not imply that the various components are separate physical components that are separately connected to form pin protector 100. Although a pin protector which is formed from separate components is within the scope of the claimed invention.

Alignment sections 160 are attached to bottom face 130 and project outward from bottom face 130 away from top face 120. Alignment sections 160 are located on opposite sides of one another and run parallel to one another as illustrated in FIG. 1B. However, pin protector 100 may be arranged such that alignment sections 160 are not parallel to one another. For example, alignment sections 160 may be positioned diagonal or perpendicular to one another. Also, alignment sections 160 could be arcuate. Alignment sections 160 aide in aligning pin protector 100 with various types of hardware that are used to secure integrated circuits to various connection devices. For example, alignment sections 160 may be used to align pin protector 100 to the various types of snaps or connectors that are often used to attach a processor to a heat sink. Thus, alignment sections 160 provide reference points for engaging complementary features on an integrated circuit to be protected to aid in aligning pin protector 100 properly on such integrated circuit.

Ribs 170 are also attached to bottom face 130 and project outward from bottom face 130 away from top face 120; Ribs 170 are located on opposite sides of one another and run parallel to one another and perpendicular with respect to alignment sections 160 as illustrated in FIG. 1B. However, pin protector 100 may be arranged such that ribs 170 are aligned parallel with alignment sections 160 or arranged such that ribs 170 are positioned diagonal or in arcuated relationship to one another. Ribs 170 operate to stiffen and strengthen pin protector 100. When pin protector 100 is manufactured, cutout sections 190 are cutout of sides 140. As a result of creating cutout sections 190, pin protector 100 is weakened. Ribs 170 are therefore provided to stiffen and strengthen pin protector 100 and reduce the weakness resulting from cutouts 190. Ribs 170 also operate to strengthen protector 100 to help prevent bottom face 130 from easily being pressed down upon the pins of the integrated circuit being protected even if protector 100 does not include cutouts 190. For example, if someone or something accidentally presses down on top face 120 while protector 100 is protecting pins, the ribs add strength to the protector to help prevent top face 120 from deflecting downward thereby preventing bottom face 130 from contacting any pins that are being protected by pin protector 100.

Installation cutout sections 190 are cutout of the center of two sides 140. As illustrated in FIG. 1 B, installation cutout sections 190 are located on opposite sides. Installation cutout sections 190 provide users with an easily accessible ergonomic gripping point. The gripping point is useful during installation and removal so that users will not interfere or damage the integrated circuit being protected while removing or installing pin protector 100. For example, if a user wishes to remove pin protector 100 from a processor, for example, when the user wishes to install the processor into a socket of a motherboard, the user can easily grip installation cutouts 190 and remove pin protector 100 without touching or interfering with the processor. By reducing interference with the processor, damage resulting from installation and removal is ultimately reduced.

Label viewing sections 195 are recessed wall portions of the two sides 140 that are not used for installation cutout sections 190 and are located opposite of one another as illustrated in FIG. 1B. The recessed label viewing sections 195 provide label visibility and allow users to read labels that may be near the integrated circuit or may be attached to the integrated circuit that is being protected.

Securing mechanisms 180 shown in FIGS. 1A and 1B are attached to corners 150 and protrude downward from top face 120. Securing mechanisms 180 may attach pin protector 100 to the integrated circuit or to any accompanying hardware. For example, securing mechanisms 180 would attach pin protector 100 to a processor board of a processor that is being protected. Securing mechanisms 180, in this embodiment, are resilient members that protrude downward from top face 120 and extend beyond sides 140 as illustrated by the cross sectional view of pin protector 100 in FIG. 1C. The end of securing mechanisms 180 may comprise a pointed end with an extending segment that operates as a hook to secure pin protector 100 to an integrated circuit or accompanying hardware. However, securing mechanisms 180 may include any type of fastening means, e.g. snap lock, tab, bolt, resistance fit pin, etcetera, that is capable of securing pin protector 100 to an integrated circuit or accompanying hardware, such as a heat sink.

Pin protector 100 is preferably made of some type of static-resistive plastic resin so that there is no static damage to the integrated circuit. However, pin protector 100 may be made from any static-resistant material.

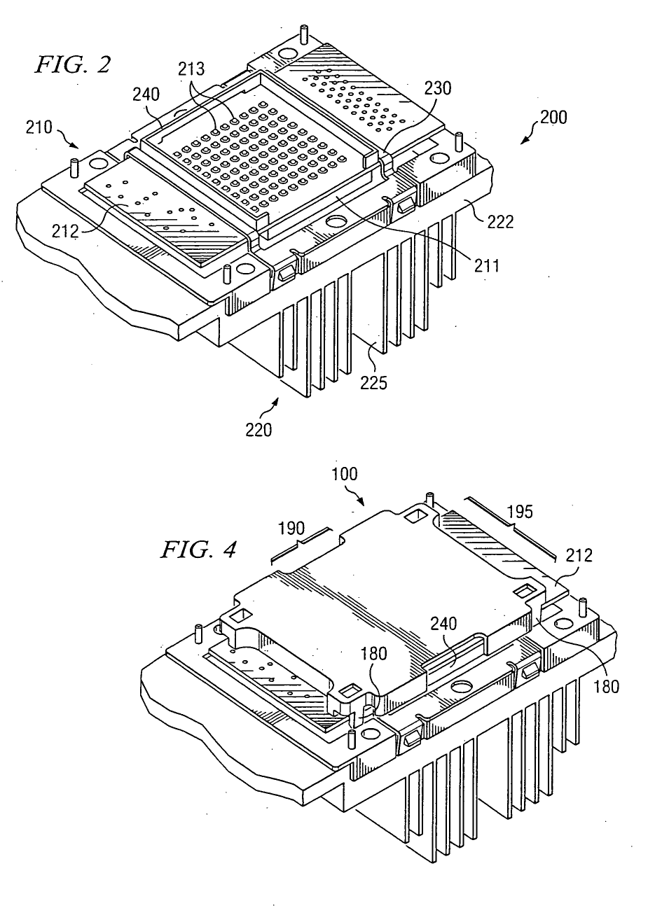

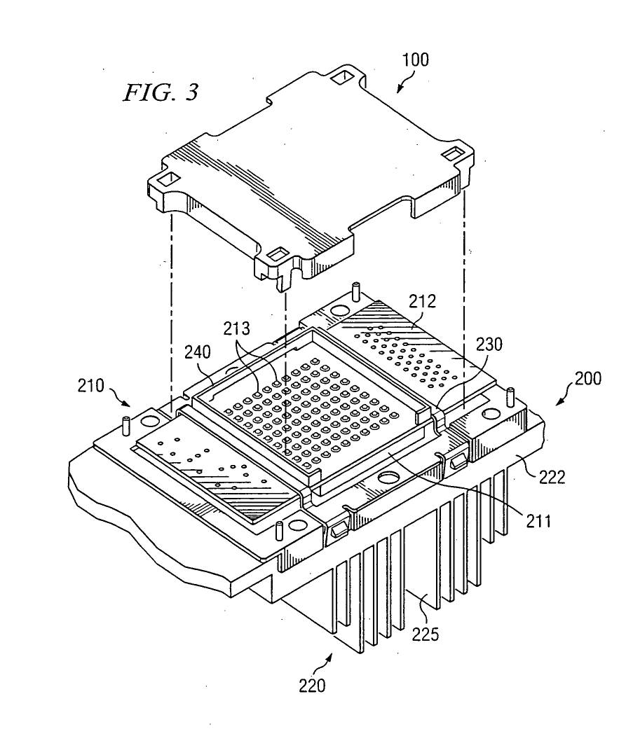

FIG. 2 illustrates a typical shipping configuration of a heatsink/processor combination 200, which is one example of an integrated circuit that pin protector 100 may be used to protect, as described further in FIGS. 3-5. However, pin protectors, as taught herein, are not limited to protecting pins of an integrated circuit in this configuration. For example, pin protectors in accordance with this disclosure may be used to protect a stand alone integrated circuit that is not connected to a circuit board. Combination 200 is comprised of processor 210, heatsink 220, retaining clips 230, and alignment shroud 240. Processor 210 includes processor chip 211, processor board 212, and processor pins 213. Heatsink 220 includes heatsink frame 222 and heatsink fins 225. The view of processor/heatsink combination 200 illustrated in FIG. 2 is an upside down view. When processor/heatsink combination 200 is mounted to a socket, the processor/heatsink combination 200 will be flipped over so that processor 210 can be mounted to a mounting socket through processor pins 213. As illustrated in FIG. 2, pins 213 on the underside of processor 210 are not covered, and heatsink 220 is connected to the top of processor 210.

Retaining clips 230 are used to attach heatsink 220 to the top of processor 210. Alignment shroud 240 is also shipped with the heatsink/processor combination 200 and is positioned around the perimeter of processor chip 211. Alignment shroud 240 is often used to insure proper alignment of processor 210 to a socket during installation.

As illustrated in FIG. 2, pins 213 are exposed and are typically shipped without protection. This lack of protection often subjects pins 213 to various types of damage that usually occur during packaging, shipping, and handling. As illustrated in FIGS. 3, 4, and 5, pin protector 100 will protect pins 213 from damage that may otherwise occur during packaging, shipment, and general handling.

FIG. 3 illustrates an exploded view of pin protector 100. FIG. 3 shows the heatsink/processor combination wherein pin protector 100 is used to protect pins 213. Similar to FIG. 2, FIG. 3 also shows processor 210 in an upside down orientation as illustrated by heatsink 220 shown underneath processor 210. Heatsink 220 is attached to the top of processor 210 by retaining clips 230. Processor board 212 is shown extending beyond retaining clips 230. Alignment shroud 240 is shown around the perimeter of pins 213. Pin protector 100 is shown elevated above processor 210 to clearly represent the location of pin protector 100 and the portion of processor 210 that pin protector 100 will cover.

As shown in FIG. 3, pin protector 100 covers at least a portion of processor chip 211 including pins 213. Pin protector 100 also extends over alignment shroud 240 and retaining clips 230. Pin protector 100 does not cover the entire processor board 212, but in alternative arrangements, pin protector 100 may be arranged to cover a larger processor area such as the entire processor board 212 or arranged to cover a smaller area. Pin protector 100 may also be implemented in certain embodiments to cover the pins of a plurality of integrated circuits that are included in an assembly. By covering pins 213, pin protector 100 protects pins 213 from the damage that usually occurs from shipping, handling, an packaging.

FIG. 4 illustrates a non-exploded view of FIG. 3. As shown in FIG. 4, pin protector 100 includes installation cutouts 190 and label recess sections 195. Pin protector 100 is snapped in place over processor chip 211 thereby covering and protecting the processor pins. Pin protector 100 is secured to processor 210 by the use of securing mechanisms 180 that attach to the underside of processor board 212. To use pin protector 100, a user may grip cutout sections 190 and push pin protector 100 down over processor 210 until securing mechanisms 180 latch onto processor board 212. Thus, it uses a complimentary feature(s) of the assembly for securing thereto. After securing mechanisms 180 latch onto processor board 212, pin protector 100 is secured to processor 210 thereby covering and protecting the processor pins. By covering and protecting the processor pins, the heatsink/processor combination may be shipped, packaged, or handled without damage to the processor pins.

Processors usually contain one label. Therefore, only one cutout label section 195 may be included in certain embodiments of pin protector 100. Yet, pin protector 100 contains two label cutout sections 195 in this example. Sections 195 are symmetrical so that pin protector 100 can be attached to processor 210 with either label cutout section 195 positioned near the label. The symmetry of pin protector 100 ultimately-leads to less assembly instructions for manufacturing.

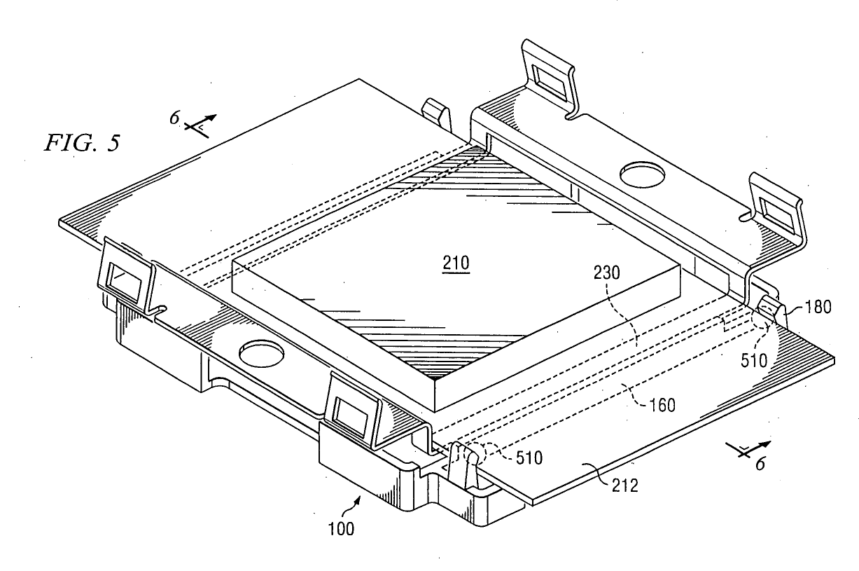

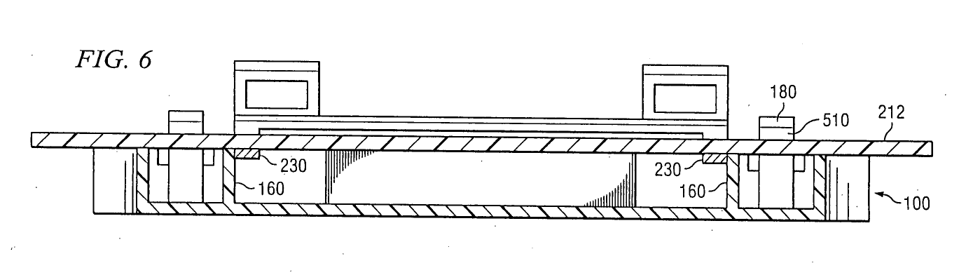

FIG. 5 illustrates an underneath view of processor 210 and pin protector 100 without a heatsink. FIG. 5 shows how pin protector 100 aligns and snaps to processor 210. Alignment occurs when alignment sections 160 align pin protector 100 with the retaining clip 230. Thus, it uses a complimentary feature(s) of assembly 200 for aligning therewith for proper coupling. FIG. 6 is a cross sectional view of FIG. 5 and illustrates the alignment of alignment sections 160 with retaining clip 230. Pin protector 100 snaps to processor board 212 by securing mechanism 180 that extends past processor board 212 so that the pointed end of securing mechanism 180 initially resiliently deflects outwardly and then snaps back to hook to processor board 212 as shown at connection-points 510. Once pin protector 100 is attached to processor 210, the processor pins are protected. Therefore, pin protector 100 will be secured to the heatsink/processor combination by securing mechanism 180 so that the pins are covered and protected throughout the shipping, handling, and packaging process. When the heatsink/ processor combination is ready for installation, a user can easily remove pin protector 100 by gripping the installation cutout sections and pulling pin protector 100 off of the heatsink/ processor combination which will expose the processor pins so that processor 210 is ready for installation.

Although pin protector 100 has been illustrated as protecting the pins of a processor, other similar pin protectors can function to protect other integrated circuit devices. By covering an integrated circuit device, pin protectors will operate to prevent a wide array of damage that may occur from shipping, handling, or packaging.

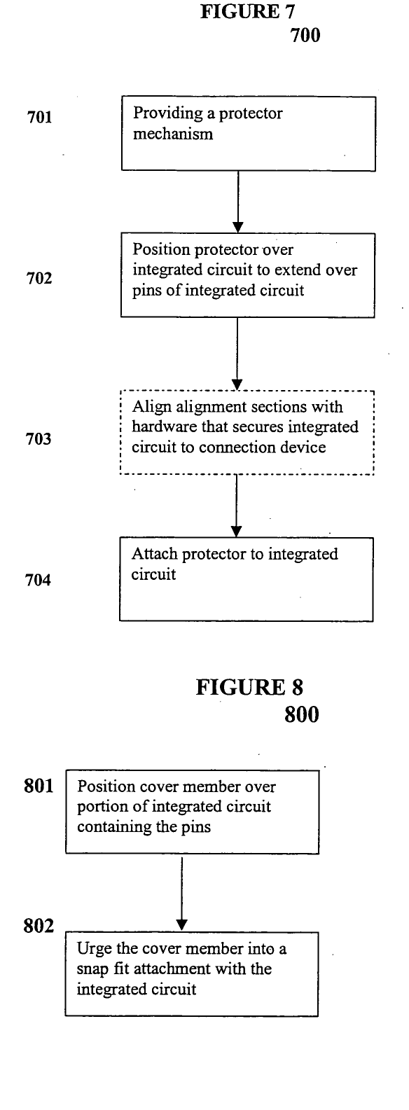

FIG. 7 is a flowchart illustrating an application of a pin protector, such as the example embodiment described above. Flow 700 illustrates a method for protecting the pins of an integrated circuit. In step 701, a protector mechanism having a top face, a bottom face, at least one alignment section, at least one rib, and at least one securing mechanism for securing to an assembly is provided. In an alternative arrangement, the protector mechanism may also have at least one installation cutout section and at least one label viewing section. In step 702, the protector mechanism is positioned over the integrated circuit so that the protector extends over the pins. Optionally, flow 700 may include step 703 wherein an alignment section is aligned with hardware that secures the integrated circuit to an assembly such as a heat sink. Alignment may also entail aligning a label viewing section with a label on the integrated circuit. After alignment, the protector is attached to the integrated circuit or accompanying assembly in step 704. Attachment may also entail gripping the protector by an installation cutout section and pressing down on the protector until the securing mechanism of the protector latches onto the integrated circuit or other portion of the assembly.

FIG. 8 is a flowchart illustrating an application of a pin protector. Flow 800 illustrates a method for protecting the pins of an integrated circuit. In step 801, a cover member is positioned over a portion of the integrated circuit containing pins, and in step 802, the cover member is urged into a snap fit attachment with the integrated circuit.

Although the pin protector has been described as shown in a rectangular shape, it should be understood that the pin protector is not limited to the specific embodiment described above, but may be implemented in various ways as described herein. For instance, pin protector 100 is not limited to the shape illustrated in FIGS. 1A-1C and 3-5. Pin protector 100 may take the form of various shapes such as a rectangular, circle, octagon, or triangle. The pin protector may also be arranged such that it may take the form of any other shape that is complimentary to (or substantially mimics) the shape of an integrated circuit to be protected or the shape of an assembly that contains the integrated circuit to be protected. For example, if an integrated circuit were in the shape of a circle, then the pin protector could be in the shape of a circle in order to protect the integrated circuit's pins. Although securing mechanisms 180 are shown attached to corners 150, pin protector 100 may be situated so that securing mechanisms 180 are not positioned at corner 150, but may be positioned anywhere on pin protector 100 so as not to interfere with the protection of an integrated circuit's pins.

Pin protector 100 is shown in FIG. 1B with two ribs 170 and two alignment sections 160. However, an alternative embodiment of pin protector 100 may be arranged so that a pin protector does not include any ribs or alignment sections or a pin protector may include more or less than two ribs and two alignment sections. In addition, the ribs and alignment sections are not limited to the positions illustrated in FIG. 1B, as they may be positioned in different places of a pin protector depending on the shape and layout of the integrated circuit to be protected. FIG. 1B also illustrates pin protector 100 with two installation cutout sections 190 and two label recess sections 195. However, in alternative embodiments, a pin protector may have no such installation cutout or label recess sections, it may include greater or fewer than two installation or label viewing sections, and the label viewing and installation sections may be positioned in different locations. Similarly, although pin protector top and bottom faces 120, 130 are shown as flat surfaces in the illustrated embodiment, other configurations, e.g. an upwardly projecting dome configuration, may be employed. In such a dome shaped assembly, the top and bottom faces and the skirt could be continuous and have the same curvature such that the entire pin protector is dome shaped.

1. An apparatus for protecting pins of an integrated circuit comprising:
a cover member; and
at least one securing mechanism for securing said cover member to an assembly that includes at least one integrated circuit having pins, wherein said cover member covers at least said pins.

2. The apparatus of claim 1, said cover member comprising:
a top face;
a bottom face; and
a skirt.

3. The apparatus of claim 2, said skirt comprising:
a plurality of sides; and
a plurality of corners.

4. The apparatus of claim 2 further comprising:
at least one alignment section attached to said bottom face projecting outward from said bottom face away from said top face.

5. The apparatus of claim 4 wherein said alignment section operates to align with connection devices used to connect said integrated circuit to an assembly.

6. The apparatus of claim 2 further comprising:
at least one rib attached to said bottom face projecting outward from said bottom face away from said top face.

7. The apparatus of claim 3 wherein said securing mechanism is a snap attached to at least one of said plurality of corners projecting downward from said corner away from said top face.

8. The apparatus of claim 7 wherein said snap includes a lip located at the end of said snap for securing said apparatus to said integrated circuit.

9. The apparatus of claim 2 wherein said skirt comprises a recess wherein said recess allows for visibility of a label on said integrated circuit.

10. The apparatus of claim 1 wherein said cover member comprises a cutout wherein said cutout allows for ease of installation and removal of said cover member.

11. The apparatus of claim 1 wherein said apparatus is made from a static resistive plastic resin.

12. The apparatus of claim 3 wherein said apparatus further comprises:
two label recess sections wherein said label recess sections are recesses in two opposing sides of said plurality of sides, wherein said label recess sections provide for visibility of at least one label on said integrated circuit; and
two installation cutout sections wherein said installation cutout sections are cutout of two opposing sides of said plurality of sides not including said label recess sections, wherein said installation cutout sections provide for ease of installation and removal of said apparatus.

13. The apparatus of claim 12 wherein said apparatus is symmetrical.

14. The apparatus of claim 1 wherein said apparatus is sized to cover and protect the pins of a plurality of integrated circuits.

15. The apparatus of claim 2 wherein said top face and bottom face are rectangular.

16. A protector for protecting pins of a microprocessor, comprising:
a rectangular shaped top face;
a rectangular shaped bottom face;
a plurality of sides;
a plurality corners;
a plurality of securing mechanisms attached to said corners projecting downward from said corner away from said top face;
two label viewing sections formed in two opposing sides of said plurality of sides wherein said label viewing sections provide visibility for at least one label on said microprocessor;
two installation cutout sections taken from two opposing sides of said plurality of sides not containing said label viewing sections wherein said installation cutout sections provide ease of installation and removal of said protector;
at least two alignment sections; and
at least two ribs operating to strengthen said protector.

17. The protector of claim 16 wherein said protector is made from a static resistive plastic resin.

18. The protector of claim 16 wherein said protector is symmetrical.

19. The protector of claim 16 wherein said protector is sized to fit around alignment devices located around said pins.

20. The protector of claim 19 wherein said two alignment sections align with retaining devices used to secure said microprocessor to an assembly.

21. The protector of claim 16 wherein said two alignment sections align with retaining clips used to secure said microprocessor to a heat sink.

22. The protector of claim 16 wherein said alignment sections are attached to said bottom face projecting outward from said bottom face away from said top face wherein said alignment sections run parallel to said label cutout sections.

23. The protector of claim 22 wherein said ribs are attached to said bottom face projecting outward from said bottom face away from said top face wherein said ribs run parallel to said installation cutout sections.

24. The protector of claim 16 wherein said securing mechanisms extend beyond said plurality of sides and include a mechanical fit located at the end of said securing mechanism wherein said mechanical fit secures said protector to said microprocessor.

25. A shipping assembly for shipping an integrated circuit having pins, said assembly comprising:
a base mechanism;
a connection device for securing said integrated circuit to said base mechanism; and
a pin protector installed over said pins of said integrated circuit, wherein said pin protector comprises:
a cover member; and
at least one securing mechanism for securing said pin protector to said base mechanism wherein said pin protector covers said pins.

26. The shipping assembly of claim 25 wherein said cover member comprises:
a top face;
a bottom face; and
a skirt comprising:
a plurality of sides; and
a plurality of corners.

27. The shipping assembly of claim 26 further comprising:
at least one alignment section attached to said bottom face projecting outward from said bottom face away from said top face wherein said alignment section operates to align with said connection device.

28. The shipping assembly of claim 26 wherein:
said skirt further comprises a recess wherein said recess allows for visibility of a label on said integrated circuit; and
said cover member comprises a cutout wherein said cutout allows for ease of installation and removal of said cover member.

29. The shipping assembly of claim 25 wherein said base assembly is a heatsink and said integrated circuit is a microprocessor.

30. A method of protecting the pins of an integrated circuit, said method comprising:
providing a protector mechanism having a top face, a bottom face, a plurality of sides, a plurality of corners, at least one alignment section, at least one rib, and at least one securing mechanism;
positioning said protector over said integrated circuit such that said protector extends over said pins; and
attaching said protector to said integrated circuit.

31. The method of claim 30 wherein said protector mechanism further includes at least one installation cutout section and at least one label cutout section whereby said installation cutout section provides for ease of installation and removal of said protector mechanism and said label cutout section provides for visibility of at least one label on said integrated circuit.

32. The method of claim 30 further comprising:
aligning said alignment section with hardware used to secure said integrated circuit to an assembly;

33. The method of claim 32 wherein said aligning said alignment section further comprises:
aligning said label cutout section with said label.

34. The method of claim 30 wherein attaching said protector comprises:
gripping said protector by said installation cutout section; and
pressing said protector downward until said securing mechanism connects onto said integrated circuit.

35. A mechanism for protecting the pins of an integrated circuit, said mechanism comprising:
a means for covering pins of an integrated circuit;
a means for aligning said covering means to an assembly including an integrated circuit; and
a means for securing said covering means to said assembly.

36. The mechanism of claim 35 wherein said securing means operates to secure said covering means to said integrated circuit.

37. The mechanism of claim 35 further comprising:
a means for strengthening said covering means.

38. The mechanism of claim 35 further comprising:
a means for providing visibility of labels located on said integrated circuit.

39. A method of protecting the pins of an integrated circuit comprising:
positioning a cover member over the portion of the integrated circuit containing the pins; and
urging the cover member into a snap fit attachment with the integrated circuit.
